(19) United States
(12) Patent Application Publication
(10) Pub. No.: US 2026/0047033 A1
(43) Pub. Date: Feb. 12, 2026

(54) SLOT SUPPORTED BAFFLE FOR PARTITIONING HEATED AIR

(71) Applicant: Lenovo (Singapore) Pte. Ltd., Singapore (SG)

(72) Inventor: Bryan Roy Binda, Cary, NC (US)

(21) Appl. No.: 18/795,853

(22) Filed: Aug. 6, 2024

(51) Int. Cl. H05K 7/20; G06F 1/20

(52) U.S. Cl. CPC H05K 7/20145; G06F 1/20

(57) ABSTRACT

A baffle partitions heated air from a actively cooled container (ACC) installed on a first slot of a system board in a chassis of a computing device. The baffle includes a body having a width configured to fit in a second slot laterally spaced from the first slot and under a longitudinal extent of the ACC. The body has a height and length configured to partition heated air from the ACC from moving from a first side of the body to a second side of body. The body has multiple cutouts forming at least one tab for retentively engaging with the second slot.

### BACKGROUND

In the realm of computer hardware, particularly in high-performance computing and gaming, the efficiency of a graphics processing unit (GPU) is paramount. The thermal management of GPUs is a critical aspect that significantly impacts performance, longevity, and reliability. Traditional cooling solutions often struggle to address the complex thermal dynamics in compact and densely packed systems, leading to the need for innovative approaches to enhance airflow and heat dissipation.

### SUMMARY

A baffle partitions heated air from a heat generating unit such as an actively cooled container (ACC) installed on a first slot of a system board in a chassis of a computing device. The baffle includes a body having a width configured to fit in a second slot laterally spaced from the first slot and under a longitudinal extent of the ACC. The body has a height and length configured to partition heated air from the ACC from moving from a first side of the body to a second side of body. The body has multiple cutouts forming at least one tab for retentively engaging with the second slot.

### BRIEF DESCRIPTION OF THE DRAWINGS

FIG. 1 is a perspective view of an example baffle according to an example embodiment.

FIG. 2 is a side view of an example baffle that includes multiple cutouts according to an example embodiment.

FIG. 3 is a perspective block diagram representation of a system board having multiple CEM slots and an installed baffle according to an example embodiment.

FIG. 4 is a perspective block diagram illustrating a GPU container plugged into the first CEM slot of system board according to an example embodiment.

FIG. 5 is a method of installing a means of blocking airflow from an exhaust of an actively cooled GPU to an air input of the actively cooled GPU according to an example embodiment.

### DETAILED DESCRIPTION

In the following description, reference is made to the accompanying drawings that form a part hereof, and in which is shown by way of illustration specific embodiments which may be practiced. These embodiments are described in sufficient detail to enable those skilled in the art to practice the invention, and it is to be understood that other embodiments may be utilized and that structural, logical and electrical changes may be made without departing from the scope of the present invention. The following description of example embodiments is, therefore, not to be taken in a limited sense, and the scope of the present invention is defined by the appended claims.

Current Graphics Processing Units (GPUs) come packaged in an actively cooled container (ACC) that plug into a first CEM (Card Electromechanical) slot of a computer system board within a computer case. A CEM slot is a 4, 8, or 16-lane slot that connects a system board to an add-in card (AIC). CEM slots are found in many desktop PCs, workstations, and servers. Multiple slots are typically located on a system board within a computer chassis and are designed to accommodate different types of cards and devices. While the term CEM slot is used, the term is not meant to be limited to current slots that are designated as CEM slots but is meant to cover any type of slot into which can support components such as GPUs.

One of the primary challenges in GPU cooling is the management of airflow within the confined spaces of computer cases. Typically, GPUs emit heat from one or more of a top, bottom, and sides, and heated air must be efficiently expelled to prevent overheating. The proximity of other components, including the system board and adjacent expansion cards, often restricts airflow, leading to the expelled hot air being drawn back toward a cooling air inlet of the GPU resulting in suboptimal cooling performance. Additionally, the variability in system board and GPU designs complicates the creation of a one-size-fits-all cooling solution.

The inventive subject matter includes a baffle designed to partition GPU hot air exhaust from the cooling air inlet of the GPU or other actively cooled container. This baffle is uniquely designed to integrate with a second CEM slot adjacent to or near the first CEM slot that supports the GPU. The primary function of the second slot is mechanical retention of the baffle, ensuring stability and alignment without relying on electrical connectivity. The baffle may have a length sufficient to greatly reduce expelled hot air being drawn back toward components separated from the GPU by the baffle. In one example, the baffle runs an entire length of a computer chassis.

By improving airflow management around the GPU, the baffle can significantly enhance cooling efficiency, thereby boosting GPU performance, reducing thermal throttling, and extending the GPU and other system component operational lifespans.

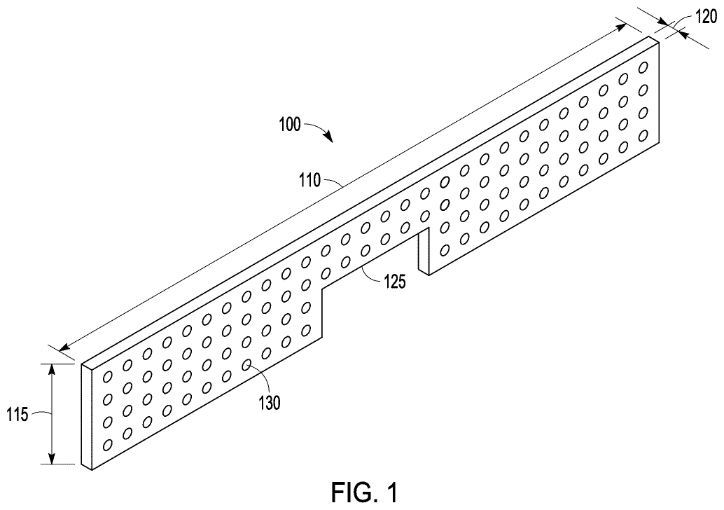

FIG. 1 is a perspective view of an example baffle 100. Baffle 100 has a length 110, height 115, and width 120. The dimensions shown are not to scale for convenience of illustration. The length 110 may be selected to run an entire length of a chassis of a computer, the length of system board having CEM slots, or a length selected to selectively reduce heated air exhausted from a GPU installed in a different CEM slot. The height 115 of baffle 100 may be selected to match a distance an installed GPU is from the system board to create a physical barrier to air movement. The width 120 of baffle 100 may be the same throughout the height and length of baffle 100 and selected to retentively mechanically mate with the CEM slot. The GPU itself may also help maintain an installed position of the baffle 100 by creating a barrier from moving the baffle 100 up and out of the CEM slot it is installed in. The CEM slots may also include plastic or metal retention clips. The clips may be spring-loaded and designed to flex inward when a card is inserted into the slot providing further retentive force on the baffle 100.

In one example the baffle 100 is molded or cut from a sheet of material with at least one punchout or cutout 125 to provide a shape conformed around one or more components in a path of the baffle 100. The baffle may include an array of perforations 130 that are spaced to allow for customizable punch-outs, enabling multiple cutouts to be formed to enhance a seal or create a tight around the components. The perforations and the array of perforations are not necessarily shown to scale for ease of illustration. The array of perforation 130 enables the baffle to be customized with punchouts to mold precisely around various system board components and a bottom of the GPU. Such customization allows accommodating a wide range of system board and GPU configurations, ensuring a sufficient seal to optimize airflow direction and efficiency and allow direction of heated air away from the other system board components.

The array of perforations 130 may include individual perforations or holes having a spacing that facilitates removing or punching out portions of the baffle by simply cutting or tearing along horizontal and vertical strings of perforations. The total area of the holes should be much less than the area of the baffle to prevent significant leakage of heated air through the baffle 100.

Utilizing a CEM slot for securing the baffle 100 provides a robust mechanical connection that is independent of the electrical functions of the GPU or motherboard. This approach not only simplifies the installation process but also enhances the structural integrity of the cooling setup. Some CEM slots may have retention clips that snap into place against the edges of the baffle 100, holding it securely in the slot. The clips provide tension against the sides of the card, preventing it from slipping out of the slot accidentally.

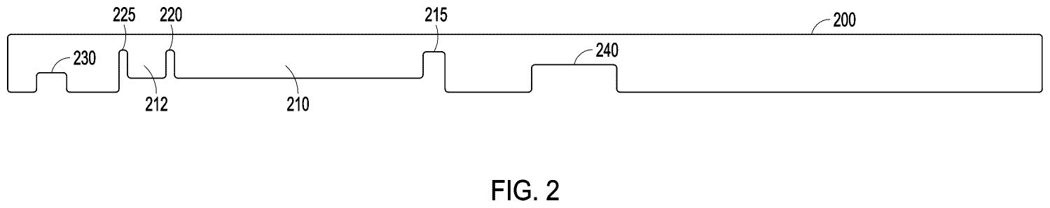

FIG. 2 is a side view of an example baffle 200 that includes multiple cutouts. Baffle 200 has a length in one example that corresponds to the length of a system board having CEM slots into which baffle 200 is secured when installed to block movement of heated air exhausted from a GPU container from being directly drawing back into the GPU container which may be actively cooled.

Baffle 200 includes two CEM slot tabs 210 and 212 that each have a length that is less than or equal to a length of two portions of a CEM slot. A CEM slot may have two different sized slots separated by a divider. Tab 210 has a length corresponding to a longer portion of the CEM slot and is formed between adjacent CEM slot cutouts 215 and 220. Tab 212 has a length corresponding to a shorter portion of the CEM slot is and formed between adjacent cutouts 225 and 220. Cutout 220 corresponds to the CEM slot divider.

The cutouts 215, 220, 225 are configured to accommodate the divider and outside edges of the CEM slot when plugged into the CEM slot. In some examples, the cutouts may have a profile that matches a non-linear profile of a component.

Tabs 210 and 212 have heights that are less than the height of the other portions of the baffle 200. Since the CEM slots do not extend all the way the system board, the height of the tables 210 and 212 are selected to ensure that the other portions of the baffle 200 that do not have tabs, can engage or rest upon the system board to prevent or minimize heated air flow through baffle 200.

Baffle 200 has additional cutouts 230 and 240 in one example to enable the cutout to conform to the profile of the system board which may have other components creating a non-linear profile along the path of the baffle 200 when installed. While two such cutouts are shown, more or fewer cutouts may be provided. Such cutouts may be used to accommodate other components like capacitors, VRMs (Voltage Regulator Modules), or additional cooling units that might intersect a path of baffle 200 when installed in the CEM slot.

Baffle 200 is illustrated without perforations for ease of illustration but may contain perforations as illustrated in baffle 100. In one example, the baffle 200 may be initially formed with the tabs 210 and 212 as such tabs and corresponding cutouts 215, 220 and 225. The perforations need not extend above such cutouts but may be formed laterally from the preformed tabs. The baffle 200 may be formed of plastic that is printed or injection molded or laser cut from a sheet of plastic. If printed or injection molded, the width of the baffle may vary from the width of tabs that fit in the CEM slots. The perforations may be drilled, or laser cut if molding or laser cutting is used to form the baffle 200. Other materials may be used for the baffle 200 that can block the flow of heated air. In one example, it may be desired to use materials that are thermally insulating as opposed to thermally conducting.

The ability of the baffle 100, 200 to adapt to different slots, system board types, and GPU models makes it a versatile solution suitable for a broad spectrum of computer systems, from custom-built gaming rigs to enterprise-level servers.

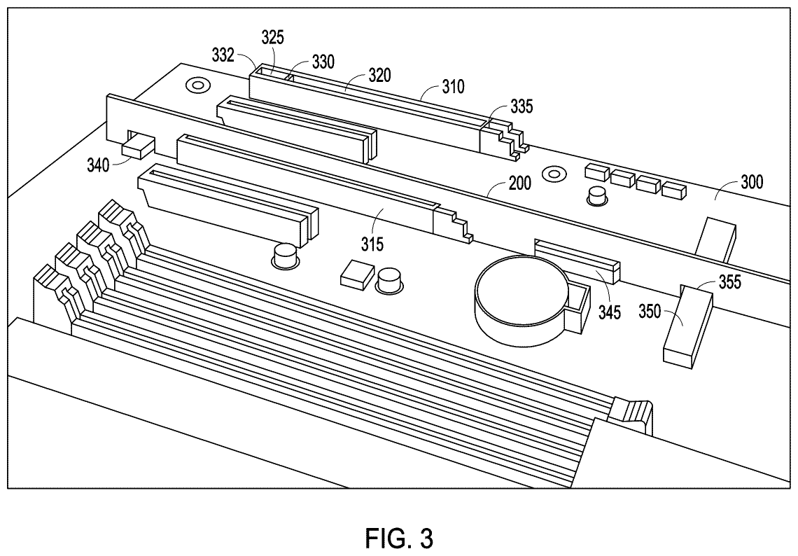

FIG. 3 is a perspective block diagram representation of a system board 300 having multiple CEM slots and an installed baffle 200. System board 300 includes a first CEM slot 310 and a second CEM slot 315. Baffle 200 is shown installed in the second CEM slot 315. First CEM slot 310 has a configuration that is the same as second CEM slot 310. First CEM slot 310 includes a first slot 320 and a second slot 325 separated by a divider 330. Tabs 210 and 212 of baffle 200 are configured to fit in the first and second slots 320 and 325. CEM slot 310 also has a first outside edge 332 corresponding to cutout 225 and a second outside edge 335 that corresponds to cutout 215. Edge 335 may also include a latch or other mechanism, making cutout 215 wider than cutouts 220 and 225. The system board also supports two components 340 and 345 that correspond to cutouts 230 and 240 respectively. An additional component 350 in the path of baffle 200 may cause the addition of a further slot 355 in baffle 200.

Observable in FIG. 3 is that the combination of slots and tabs in the baffle 200 provide a barrier to along a line extending longitudinally from CEM slot 315 along a corresponding length of the system board 300 that blocks airflow. The top of baffle 200 is shown as linear to match a bottom of a GPU container of a GPU that may be installed in first CEM slot 310.

In one example, the baffle 200 is planar. In further examples, the baffle 200 may be formed in a serpentine shape to avoid components. If formed in a serpentine shape, a top of the baffle 200 should still be in contact with or near the GPU container to maintain its ability to impede GPU exhaust from progressing to the GPU air inlet. The serpentine shape may be used to selectively place components on either side of the baffle 200. A component that generates significant heat that is in the path of a straight baffle may be placed on the GPU side of the baffle to avoid adding heat to an air inlet of the GPU.

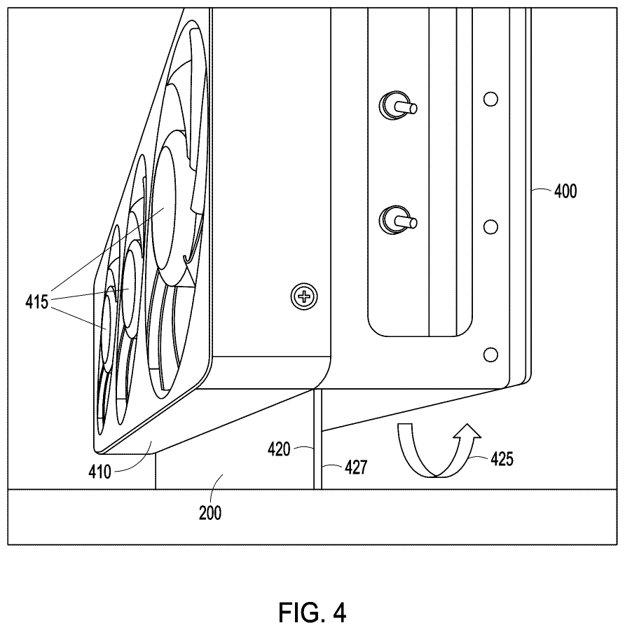

FIG. 4 is a perspective block diagram illustrating a GPU container 400 plugged into the first CEM slot 310 of system board 300. The baffle 200 is also visible, engaging a bottom 410 of the container 400. Inlet fans 415 provide active cooling to draw air from a first side 420 of baffle 200 and exhaust air 425 is shown being exhausted (represented by an arrow) from the bottom 410 on a second side 427 of baffle 200. The exhaust air 425 is heated from operation of the GPU within the GPU container 400 and is blocked from progressing to the first side of baffle 200.

GPU container 400 in one example has a flat or linear bottom 410 and rests upon a top of the baffle 200, helping to retain the baffle 200 in position. Further GPU containers may not have a flat bottom 410 in which case the top of the baffle 200 may be configured either through the use of the array of perforations 130 or being cut to match a bottom profile of the GPU container 400 to minimize the flow of heated air through or around the baffle 200.

In one example experiment, a GeForce 4080 GPU was equipped with a thermocouple placed on an air inlet edge. The GPU was run and stressed to the max at a thermal design power (TDP) of 320 watts. A temperature of inlet air was measured at 54.8 C without a baffle in place and was measured at 41.9 C with the baffle in place. The reduction in hot air circulation was significant, possibly leading to longer life spans of the GPU and a reduction in performance throttling which may occur should the GPU become too hot.

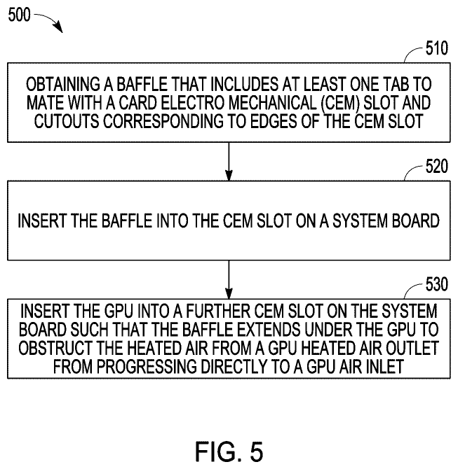

FIG. 5 is a method 500 of installing a means of blocking airflow from an exhaust of an actively cooled GPU to an air input of the actively cooled GPU. Method 500 begins at operation 510 by obtaining a baffle that includes at least one tab to mate with a Card Electromechanical (CEM) slot and cutouts corresponding to edges of the CEM slot. At operation 520, the baffle is inserted into the CEM slot on a system board. The GPU is then inserted at operation 530 into a further CEM slot on the system board. The GPU has active cooling with an air inlet and a heated air outlet. The heated air outlet and air inlet are on opposite sides of the baffle and the baffle extends under the GPU to obstruct the heated air from the heated air outlet from progressing directly to the air inlet.

### Examples

1. A baffle partitions heated air from an actively cooled container (ACC) installed on a first slot of a system board in a chassis of a computing device. The baffle includes a body having a width configured to fit in a second slot laterally spaced from the first slot and under a longitudinal extent of the ACC. The body has a height and length configured to partition heated air from the ACC from moving from a first side of the body to a second side of body. The body has multiple cutouts forming at least one tab for retentively engaging with the second slot.

2. The baffle of example 1 wherein the first and second slots are (Card Electromechanical) CEM slots.

3. The baffle of any of examples 1-2 wherein the cutouts form at least two tabs for retentively engaging with the second slot.

4. The baffle of any of examples 1-3 wherein the cutouts include a component cutout corresponding to a component supported by the system board to mold the baffle around the component.

5. The baffle of any of examples 1˜4 wherein the at least one tab has a depth that is shorter than a depth of a full depth of the baffle such that the full depth of the baffle engages with a surface of the system board to impede airflow through the baffle.

6. The baffle of example 5 wherein a top of the baffle engages a bottom of the ACC.

7. The baffle of any of examples 1-6 and further including an array of perforations for facilitating punching out of additional cutouts to mold around components in a path of the baffle.

8. The baffle of any of examples 1-7 wherein the baffle is constructed of plastic.

9. A baffle for partitioning heated air from an actively cooled container (ACC) installed on a first slot of a system board in a chassis of a computing device, the baffle including a body having a width configured to fit in a second slot laterally spaced from the first slot and under a longitudinal extent of the ACC, the body having a height and length configured to partition heated air from the ACC from moving from a first side of the body to a second side of body, the body having three vertical cutouts forming two tabs having a tab length and tab width to fit in the second slot, the vertical cutouts configured to fit over edges and a divider of the second slot.

10. The baffle of example 9 wherein the first and second slots are (Card Electromechanical) CEM slots.

11. The baffle of any of examples 9-10 wherein the cutouts include a component cutout corresponding to a component supported by the system board to mold the baffle around the component.

12. The baffle of any of examples 9-11 wherein the tabs have a depth that is shorter than a depth of a full depth of the baffle such that the full depth of the baffle engages with a surface of the system board to impede airflow through the baffle.

13. The baffle of example 12 wherein a top of the baffle engages a bottom of the ACC.

14. The baffle of any of examples 9-13 and further including an array of perforations for facilitating punching out of additional cutouts to mold around components in a path of the baffle.

15. The baffle of any of examples 9-14 wherein the baffle is constructed of plastic.

16. A system includes a system board having a first (Card Electromechanical) CEM slot and a laterally spaced second CEM slot, a graphics processing unit (GPU) installed on the first CEM slot, the GPU having an active cooling system comprising an air intake and an exhaust spaced from the air intake, the baffle having two tabs retentively installed in the second CEM slot, the baffle running under a longitudinal extent of the GPU and partitioning the air intake and exhaust. The baffle includes a body having a height and length configured to obstruct heated air from the GPU exhaust from moving from a first side of the body to a second side of body.

17. The system of example 16 wherein the body includes an array of perforations configured to enable forming cutouts to conform the body to one or more components supported by the system board along the length of the body.

18. The system of any of examples 16-17 wherein the tabs are formed with cutouts to permit installation of the baffle in the second CEM slot and wherein the baffle further includes a component cutout corresponding to a component supported by the system board to mold the baffle around the component.

19. The system of any of examples 16-18 wherein the two tabs have a depth that is shorter than a depth of a full depth of the baffle such that the full depth of the baffle engages with a surface of the system board to impede airflow through the baffle.

20. The system of example 19 wherein a top of the baffle engages a bottom of the GPU.

21. A baffle for diverting heated air from a graphics processing unit (GPU) installed on a first (Card Electromechanical) CEM slot of a system board in a chassis of the computing device, the baffle including a body having a width configured to fit in a second CEM slot laterally spaced from the first CEM slot and under a longitudinal extent of the GPU, the body having a height and length configured to obstruct heated air from the GPU from moving from a first side of the body to a second side of body, and the body having an array of perforations configured to enable forming cutouts to conform the body to one or more components supported by the system board along the length of the body.

Although a few embodiments have been described in detail above, other modifications are possible. For example, the logic flows depicted in the figures do not require the particular order shown, or sequential order, to achieve desirable results. Other steps may be provided, or steps may be eliminated, from the described flows, and other components may be added to, or removed from, the described systems. Other embodiments may be within the scope of the following claims.

1. A baffle for partitioning heated air from an actively cooled container (ACC) installed on a first slot of a system board in a chassis of a computing device, the baffle comprising:
a body having a width configured to fit in a second slot laterally spaced from the first slot and under a longitudinal extent of the ACC;
the body having a height and length configured to partition heated air from the ACC from moving from a first side of the body to a second side of body; and
the body having multiple cutouts forming at least one tab for retentively engaging with the second slot.

2. The baffle of claim 1 wherein the first and second slots comprise (Card Electromechanical) CEM slots.

3. The baffle of claim 1 wherein the cutouts form at least two tabs for retentively engaging with the second slot.

4. The baffle of claim 1 wherein the cutouts include a component cutout corresponding to a component supported by the system board to mold the baffle around the component.

5. The baffle of claim 1 wherein the at least one tab has a depth that is shorter than a depth of a full depth of the baffle such that the full depth of the baffle engages with a surface of the system board to impede airflow through the baffle.

6. The baffle of claim 5 wherein a top of the baffle engages a bottom of the ACC.

7. The baffle of claim 1 and further comprising an array of perforations for facilitating punching out of additional cutouts to mold around components in a path of the baffle.

8. The baffle of claim 1 wherein the baffle is constructed of plastic.

9. A baffle for partitioning heated air from an actively cooled container (ACC) installed on a first slot of a system board in a chassis of a computing device, the baffle comprising:
a body having a width configured to fit in a second slot laterally spaced from the first slot and under a longitudinal extent of the ACC;
the body having a height and length configured to partition heated air from the ACC from moving from a first side of the body to a second side of body;
the body having three vertical cutouts forming two tabs having a tab length and tab width to fit in the second slot, the vertical cutouts configured to fit over edges and a divider of the second slot.

10. The baffle of claim 9 wherein the first and second slots comprise (Card Electromechanical) CEM slots.

11. The baffle of claim 9 wherein the cutouts include a component cutout corresponding to a component supported by the system board to mold the baffle around the component.

12. The baffle of claim 9 wherein the tabs have a depth that is shorter than a depth of a full depth of the baffle such that the full depth of the baffle engages with a surface of the system board to impede airflow through the baffle.

13. The baffle of claim 12 wherein a top of the baffle engages a bottom of the ACC.

14. The baffle of claim 9 and further comprising an array of perforations for facilitating punching out of additional cutouts to mold around components in a path of the baffle.

15. The baffle of claim 9 wherein the baffle is constructed of plastic.

16. A system comprising:
a system board having a first (Card Electromechanical) CEM slot and a laterally spaced second CEM slot;
a graphics processing unit (GPU) installed on the first CEM slot, the GPU having an active cooling system comprising an air intake and an exhaust spaced from the air intake;
a baffle having two tabs retentively installed in the second CEM slot, the baffle running under a longitudinal extent of the GPU and partitioning the air intake and exhaust, wherein the baffle comprises:
a body having a height and length configured to obstruct heated air from the GPU exhaust from moving from a first side of the body to a second side of body.

17. The system of claim 16 wherein the body comprises an array of perforations configured to enable forming cutouts to conform the body to one or more components supported by the system board along the length of the body.

18. The system of claim 16 wherein the tabs are formed with cutouts to permit installation of the baffle in the second CEM slot and wherein the baffle further includes a component cutout corresponding to a component supported by the system board to mold the baffle around the component.

19. The system of claim 16 wherein the two tabs have a depth that is shorter than a depth of a full depth of the baffle such that the full depth of the baffle engages with a surface of the system board to impede airflow through the baffle.

20. The system of claim 19 wherein a top of the baffle engages a bottom of the GPU.
